(19) United States
(12) Patent Application Publication
(10) Pub. No.: US 2011/0029265 A1
(43) Pub. Date: Feb. 3, 2011

(54) METHOD AND DEVICE FOR PREDICTING A RECHARGEABLE BATTERY'S LIFETIME

(75) Inventor: Hubert Cecile Francois Martens, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/937,286

(22) PCT Filed: Apr. 9, 2009
(86) PCT No.: PCT/IB09/51500

§ 371 Date: Oct. 11, 2010

(30) Foreign Application Priority Data
Apr. 16, 2008 (EP) 08154593.1

(51) Int. Cl. G01R 31/36; H02J 7/00

(52) U.S. Cl. 702/63; 320/106

(57) ABSTRACT

A method is disclosed for determining an end of life for a rechargeable battery comprising the steps of using the battery (102), charging the battery (112) and making an estimation of a battery's life-time (128), characterized by monitoring a battery characteristic indicative for battery aging (122).

### FIELD OF THE INVENTION

The invention relates to a method for determining an end of life for a rechargeable battery comprising charging the battery and making an estimation of a battery's lifetime. The invention further relates to a device for determining an end of life for a rechargeable battery comprising a battery charger and a provision for estimation of a battery's lifetime.

### BACKGROUND OF THE INVENTION

Techniques disclosed in WO-A 2006/094287 provide a method and a device for monitoring and storing data regarding the life history of a battery with which it is associated. A manufacturer's specified life expectancy measured in battery cycles is established for the battery under normal use and then the actual use of the battery is monitored and stored. Complete cycles, partial cycles and operation of the battery outside of acceptable specifications are automatically derived into a value in units equivalent to a number of battery cycles. This derivation is compared with the manufacturer's life expectancy and adjustments to the manufacturer's life expectancy are made so that a more accurate and up-to-date estimation of battery life can be evolved over the life of the battery.

The techniques disclosed in WO-A 2006/094287 eventuate in an imprecise estimation for a battery's remaining lifetime. Firstly, operation of the device relies on establishing the manufacturer's specified life expectancy for the battery under normal use. This may induce an erroneous estimation of battery lifetime in terms of battery cycles, since the data supplied by the manufacturer may be mistakenly and additionally the import of these data may occur incorrectly by the user. Secondly, the remaining battery life is expressed in battery lifecycles rather than in units of time. The entity of battery lifecycles is not of much relevance for scheduling the battery's replacement unless a translation of battery lifecycles into units of time is being made. This translation is inevitably inaccurate through the fact that the battery lifecycle's duration is not constant due to battery aging which is not accounted for by the techniques disclosed in WO-A 2006/094287. An estimation based on battery lifecycles provides a rough upper bound when expressed in units of time since the battery lifecycle will actually decrease with the progress of battery lifecycles. Consequently, the battery is likely to fail prior to the point of time estimated by the techniques disclosed in WO-A 2006/094287. For a medical implantable device, this characteristic is by no means desirable. Thirdly, the method disclosed in WO-A 2006/094287 requires the actual use of the battery to be permanently monitored. Consequently, the monitoring device is mounted on the battery for the lifetime of the battery. This implies permanent attachment of e.g. circuitry to the battery which is not desirable in terms of energy and space consumption. For application of rechargeable batteries in implantable medical devices, this feature is not desirable.

### OBJECT OF THE INVENTION

It is an object of the invention to provide a method that allows for a precise prediction of a rechargeable battery's end of life without permanently monitoring the battery's actual use.

### SUMMARY OF THE INVENTION

The object of the invention is achieved by the method according to the invention which is characterized by monitoring a battery characteristic indicative for battery aging. The method according to the invention comprises the steps of charging the battery and making an estimation of a battery's remaining lifetime.

Here, the battery's remaining lifetime is defined as the duration from the moment of estimation, to the point of time at which a battery attains its end of life. The battery's end of life is defined as the moment at which the characteristic indicative for battery aging vanishes.

As mentioned before, the estimation of the battery's lifetime is derived from a battery characteristic that is indicative for battery aging. Battery aging will eventually culminate into the battery's end of life. By monitoring a characteristic indicative for battery aging, a battery's state of being is determined as a function of time. Thereby a translation of battery lifecycles into units of time is constitutively circumvented. As a result, a structurally precise estimation of the battery's lifetime is effectuated. Through monitoring a battery characteristic indicative for battery aging, there is no prerequisite to incorporate battery specific data establishing the normal use of the battery and the battery's lifetime under normal use to which possibly adaptations must be made based on the battery's actual use. Namely, aging intrinsically accounts for the actual use of the battery. Thereby the method according to the invention is robust regarding the battery type.

In a preferred embodiment according to the invention, a characteristic which is monotonically changing with time is used as the battery characteristic indicative for battery aging. The benefit of employing a characteristic that changes monotonically with time is that it allows for an appropriate application of methods to construct new data points outside a set of known data points for the battery characteristic indicative for battery aging.

Hence, in a further embodiment the estimation of the battery's lifetime is based on an extrapolation of data points of the battery characteristic indicative for battery aging. By extrapolating the battery characteristic to a predefined level at which the battery characteristic is agreed to be such that the battery's end of life is reached, the battery's lifetime is estimated. The application of extrapolation techniques reduces the efforts required to appropriately monitor the battery characteristic indicative for battery aging.

In a preferred embodiment according to the invention the battery characteristic indicative for battery aging is monitored at points of time at which the battery is being charged. As a result, the need for permanent monitoring is avoided.

In a further embodiment according to the invention, a battery's maximum capacity is used as the battery characteristic indicative for battery aging. The maximum capacity of a rechargeable battery is defined as a capacity attainable by the battery through a full recharge cycle. The battery's maximum capacity is a characteristic that monotonically decreases with time due to battery aging. The battery's maximum capacity is accessible for monitoring when charging the battery.

In an embodiment the battery's maximum capacity is quantified by measuring the battery's maximum capacity for at least two consecutive points of time at which the battery is being charged. Through application of extrapolation techniques to the at least two data points the battery's lifetime is estimated.

In a further preferred embodiment according to the invention the battery's maximum capacity is measured by determining a difference in a battery's state of charge before charging the battery and after charging the battery along with determining a charge added to the battery during charging the battery. The battery's state of charge is defined as the ratio of the battery's capacity and the battery's maximum capacity before use. Through measuring this relative quantity, the necessity to know the battery's initial maximum capacity is circumvented.

In an embodiment according to the invention the battery's state of charge is determined by measuring a battery's potential. In a further embodiment according to the invention a charge added during charging is determined by integrating a current flowing to the battery. The circuitry already present in a power management system attached to the medical implantable device may be utilized to determine these quantities. Namely, a power management system known for a person skilled in the art adapts its output current to an optimum value upon a battery's state of being. For that purpose it may monitor among other things a battery's potential and a time the battery is being charged.

In an embodiment according to the invention a rate of decay for the battery's state of charge is used as the battery characteristic indicative for battery aging. The rate of decay for the battery's state of charge monotonically increases with time. By determining the rate of decay for the battery's state of charge, measuring the charge added to the battery during charging is not necessary.

In a preferred embodiment according to the invention a time span between consecutive points of time at which the battery's state of charge decreases from a predetermined maximum level to a predetermined minimum level is used as the battery characteristic indicative for battery aging. The latter characteristic monotonically decreases with time. By measuring the aforementioned time spans, the prerequisite of determining the battery's state of charge is circumvented.

In a preferred embodiment according to the invention the battery's lifetime is expressed in units of time. Owing to this a precise scheduling for a battery's replacement is enabled. Employing a scheme for replacement, the arise of emergency situations due to unexpected battery failure, is prevented from.

In a further embodiment according to the invention the battery's lifetime is displayed. On the basis of that a scheme for the battery's replacement can be implemented and updated.

In the dependent claims 2 to 11 advantageous embodiments of the method according to the invention are disclosed. With reference to the set of claims it is noted that the invention also relates to all possible combinations of features and measures as defined in the claims.

A further object of the invention is to provide a device for predicting an end of life for a rechargeable battery. This object is achieved by the device according to the invention as claimed in claim 12.

The method and device according to the invention enable the replacement of rechargeable batteries, especially those as employed in implantable medical devices, on a precisely scheduled basis rather than on an emergency basis. This aspect and other aspects of the invention are apparent from and will be elucidated with reference to the examples described hereinafter.

### BRIEF DESCRIPTION OF THE DRAWINGS

The invention and its advantages are further elucidated by way of example with reference to the drawings in which:

FIG. 1 shows a flowchart representing a method for estimating a battery's lifetime based on monitoring a battery's maximum capacity.

FIG. 2 schematically depicts a monotonic decrease of a battery's maximum capacity as a function of time.

FIG. 3 shows a flowchart representing a method for estimating a battery's lifetime based on monitoring a rate of decay for the battery's state of charge.

FIG. 4 displays a battery's state of charge as a function of time in the presence of several charging events.

FIG. 5 shows a monotonic increase of the rate of decay for the battery's state of charge as a function of time.

FIG. 6 depicts a flowchart representing a method for estimating a battery's lifetime based on monitoring a time span between consecutive points of time at which the battery's state of charge decreases from a predetermined maximum level to a predetermined minimum level.

FIG. 7 displays a battery's state of charge as a function of time in the presence of several charging events wherein the battery is charged to a predetermined maximum level once a predetermined minimum level is attained by the battery's state of charge.

FIG. 8 schematically shows a monotonic decrease of a time span between consecutive points of time at which the battery's state of charge decreases from a predetermined maximum level to a predetermined minimum level

FIG. 9 schematically shows a device according to the invention comprising a battery charger, a provision for monitoring a battery characteristic indicative for battery aging and a provision for estimating a battery's end of life.

### DETAILED DESCRIPTION OF THE EMBODIMENTS

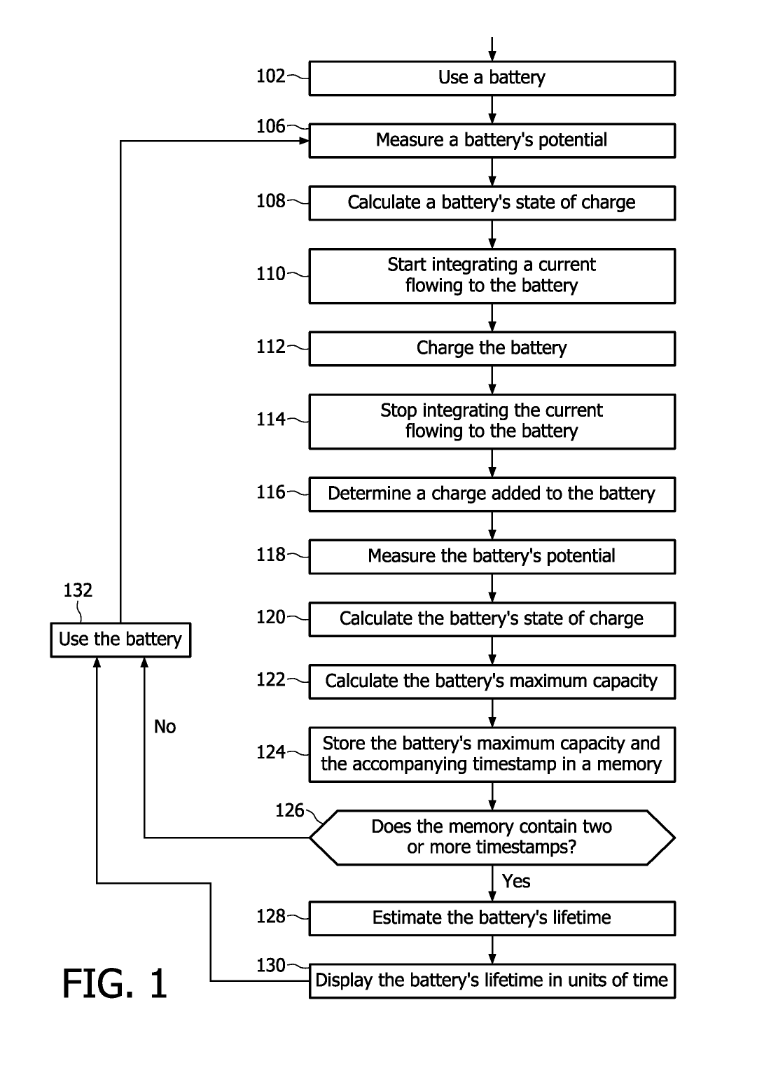

In a first and preferred embodiment according to the invention a battery's maximum capacity is monitored in order to estimate a battery's lifetime. FIG. 1 depicts a flowchart which schematically explains this embodiment. Step 102 contains using a battery prior to a first instance of charging the battery. At step 106 the battery's voltage is measured before charging the battery employing a voltmeter known per se. At step 106 the battery is operating at substantially small drain currents hence the measured battery's voltage corresponds to a battery's so called equilibrium voltage value which is usually referred to as a battery's EMF. Step 108 contains the determination of a battery's state of charge prior to charging the battery on the basis of the battery's voltage measured during step 106 and by employing a look-up table that connects the battery's voltage to the battery's state of charge. Here, the battery's state of charge SoC_{before} [%] before charging is defined according to the following equation:

$${SoC}_{before} = \frac{{Q}_{before}}{{Q}_{max}} \cdot 100 \% , \qquad [ I ]$$

wherein Q_{before} [C] is the battery's capacity before charging and Qₘₐₓ [C] is the battery's maximum capacity, i.e. the battery's maximum capacity attainable through charging. Likewise, a battery's state of charge SoC_{after} [%] after charging follows from:

$${SoC}_{after} = \frac{{Q}_{after}}{{Q}_{max}} \cdot 100 \% , \qquad [ II ]$$

wherein Q_{after} [C] is the battery's capacity after charging.

Step 112 comprises charging the battery using a charger known per se. During charging the battery, a current flowing to the battery is integrated with respect to time. The current flowing to the battery is determined by means of an ammeter known per se. At step 110 integration of the current flowing to the battery is initiated. At step 114 the integration of the current flowing to the battery is ceased after the battery has been fully charged.

Step 116 contains a computation of a charge ΔQ [C] added to the battery on the basis of integrating the current flowing to the battery during charging. The battery's charge Q_{after} [C] after charging is related to the battery's charge Q_{before} [C] before charging through the following equation:

Q_{before}=Q_{after}+ΔQ [III].

Step 118 contains measuring the battery's voltage after charging, using a voltmeter known per se. Step 120 comprises calculating the battery's state of charge after charging the battery employing the look-up table. At step 122 a battery's maximum capacity Qₘₐₓ [C] is computed on the basis of the battery's state of charge before charging, the battery's state of charge after charging and the charge to the battery added during charging. For this purpose, the equations [I], [II] and [III] are combined. By doing so, it is obtained that the battery's maximum capacity Qₘₐₓ [C] is given by the following equation:

$${Q}_{max} = \frac{100}{{SoC}_{after} - {SoC}_{before}} \cdot Δ Q , \qquad [ IV ]$$

which is an expression independent from the initial battery's initial maximum capacity. Equation [IV] is employed in step 122 to determine the battery's maximum capacity on the basis of the battery's state of charge before charging, the battery's state of charge after charging and the charge added to the battery during charging.

Step 124 comprises storing a numerical representation for the battery's maximum capacity and an accompanying timestamp in a memory. At step 126 a content of the memory is retrieved using methods known per se. In case the memory contains two or more data points, i.e. numerical values for the battery's maximum capacity accompanied with time stamps, a battery's lifetime is estimated at step 128 based on a method to be mentioned below.

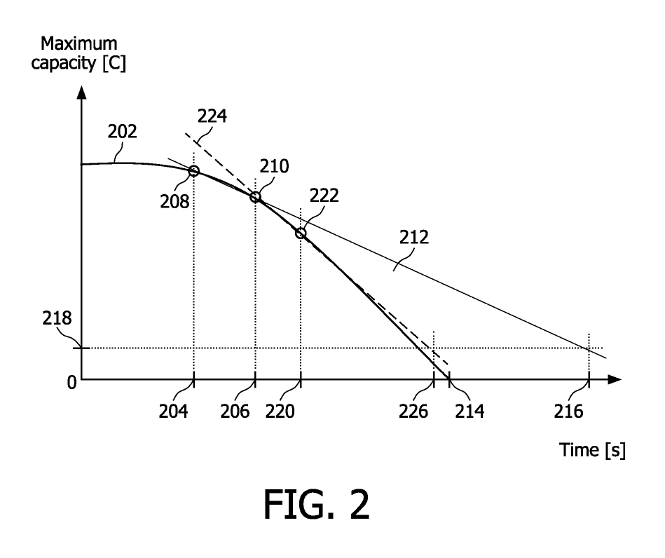

FIG. 2 schematically depicts a battery's maximum capacity 202 as a function of time. The battery is charged at a point of time 204 and consecutively at a point of time 206. The battery's maximum capacity is quantified through measurements conducted at the consecutive instances of charging the battery. A sample 208 is obtained at the point of time 204. A further sample 210 is acquired at the point of time 206. On the basis of the samples 208 and 210, a linear extrapolation 212 is derived relating to the battery's maximum capacity 202. A battery's end of life is defined as the moment at which the characteristic indicative for battery aging vanishes. Hence, the battery's end of life is attained at a point of time 214 since the battery's maximum capacity 202 then vanishes. An estimate for the point of time 214 is a point of time 216 at which the linear interpolation 212 intersects with a predefined critical level 218. The predefined critical level 218 is chosen substantially higher than zero [C] for reasons of safety.

A battery's remaining lifetime at the point of time 206 is estimated by computing the absolute value of the numerical difference between the points of time 216 and 206. In case of a consecutive recharge event at a point of time 220, a sample 222 is obtained through measurement. On the basis of the samples 210 and 222, an updated linear extrapolation 224 is established. An estimate for the point of time 214 is a point of time 226 at which the linear interpolation 224 intersects the predefined critical level 218. The battery's remaining lifetime at the point of time 220 is estimated by computing the absolute value of the numerical difference between the points of time 226 and 220.

Step 130, see FIG. 1, comprises graphically displaying the estimated battery's remaining lifetime to a user or a medical professional e.g. through telephone or internet. Hereafter the battery is used during step 132 until charging is required once more for the battery.

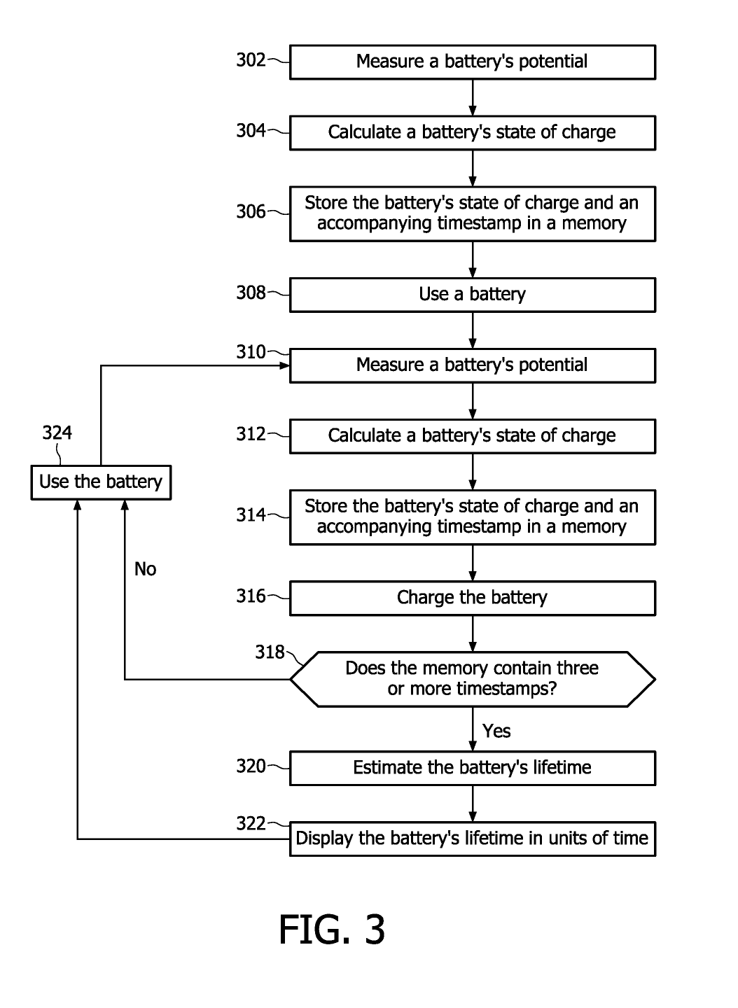

In a second embodiment according to the invention, the rate of decay for the battery's state of charge is monitored in order to estimate a battery's remaining lifetime. FIG. 3 depicts a flowchart which schematically explains this embodiment. At step 302 the battery's voltage is measured before using the battery employing a voltmeter known per se. During step 302 the battery is operating at substantially small drain currents hence the measured battery's voltage corresponds to a battery's so called equilibrium voltage value which is usually referred to as a battery's EMF. Step 304 contains the determination of a battery's state of charge prior to using the battery on the basis of the battery's voltage measured during step 302 and by employing a look-up table that connects the battery's voltage to the battery's state of charge. Step 306 comprises storing a numerical representation for the battery's maximum capacity and an accompanying timestamp in a memory. Step 308 contains using a battery prior to a first instance of charging the battery in a continuous mode. Here a continuous mode implies a constant current drain from the battery. At step 310 the battery's voltage is measured before charging the battery employing a voltmeter known per se. During step 310 the battery is operating at substantially small drain currents hence the measured battery's voltage corresponds to a battery's so called equilibrium voltage value which is usually referred to as a battery's EMF. Step 312 contains the determination of a battery's state of charge prior to using the battery on the basis of the battery's voltage measured during step 310 and by employing a look-up table that connects the battery's voltage to the battery's state of charge. Step 314 comprises storing a numerical representation for the battery's maximum capacity and an accompanying timestamp in a memory. Step 316 comprises charging the battery using a charger known per se.

At step 318 a content of the memory is retrieved using methods known per se. In case the memory contains three or more data time stamps, a battery's remaining lifetime is estimated at step 320 through a method explained below.

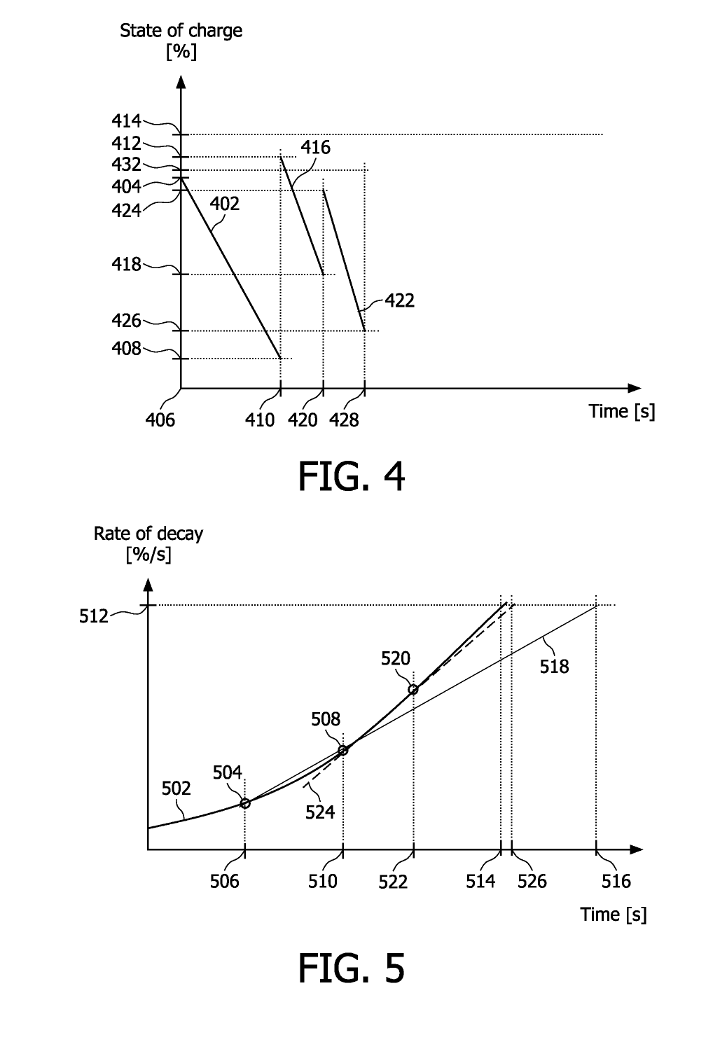

FIG. 4 schematically depicts a battery's state of charge 402 as a function of time prior to a first instance of charging the battery. By using the battery, the battery's state of charge 402 will decrease from an initial level 404 at a point of time 406 down to a level 408 at a point of time 410 at which the battery is recharged. At the point of time 410 the battery is charged to a level 412 which is not necessarily equal to a state of charge's maximum level 414. Due to using, a battery's state of charge 416 declines from the level 412 to the level 418 at a point of time 420 at which the battery is charged again. Likewise, a battery's state of charge 422 reduces from a level 424 to a level 426 at a point of time 428 at which the battery is charged once more.

FIG. 5 schematically displays a rate of decay 502 for the battery's state of charge between consecutive points of time at which the battery's state of charge is measured. A sample 504 at a point of time 506 is determined by dividing the absolute value of the numerical difference between the levels for the battery's state of charge 404 and 408 through the numerical difference between the points of time 406 and 410. Herein the point of time 506 coincides with the point of time 410. Likewise, a sample 508 at a point of time 510 is established by dividing the absolute value of the numerical difference between the levels for the battery's state of charge 412 and 418 through the numerical difference between the points of time 410 and 420. In like manner, the point of time 510 corresponds to the point of time 420. A battery's end of life is defined as the moment at which the rate of decay for the battery's state of charge approaches infinity. For reasons of safety, a battery's end of life is said to be attained in case the rate of decay for the battery's state of charge attains a predefined level 512 at a point of time 514. An estimate for the point of time 514 is a point of time 516 at which the linear interpolation 518 which is derived from the samples 504 and 508 intersects with the predefined critical level 512. A battery's remaining lifetime at the point of time 510 is estimated by computing the absolute value of the numerical difference between the points of time 510 and 516. In case of a subsequent charging event, a sample 520 is obtained at a point of time 522. The sample 520 is established by dividing the absolute value of the numerical difference between the levels for the battery's state of charge 424 and 426 through the numerical difference between the points of time 420 and 428. The point of time 522 corresponds to the point of time 428. On the basis of samples 508 and 520, an updated linear extrapolation 524 is established. An estimate for the point of time 514 is a point of time 526 at which the linear interpolation 524 intersects with the predefined critical level 518. The battery's remaining lifetime at the point of time 522 is estimated by computing the absolute value of the numerical difference between the points of time 522 and 526.

Step 322, see FIG. 3, comprises graphically displaying the estimated battery's remaining lifetime to a user or a medical professional. Hereafter the battery is used in a continuous mode during step 324 until the battery is charged again.

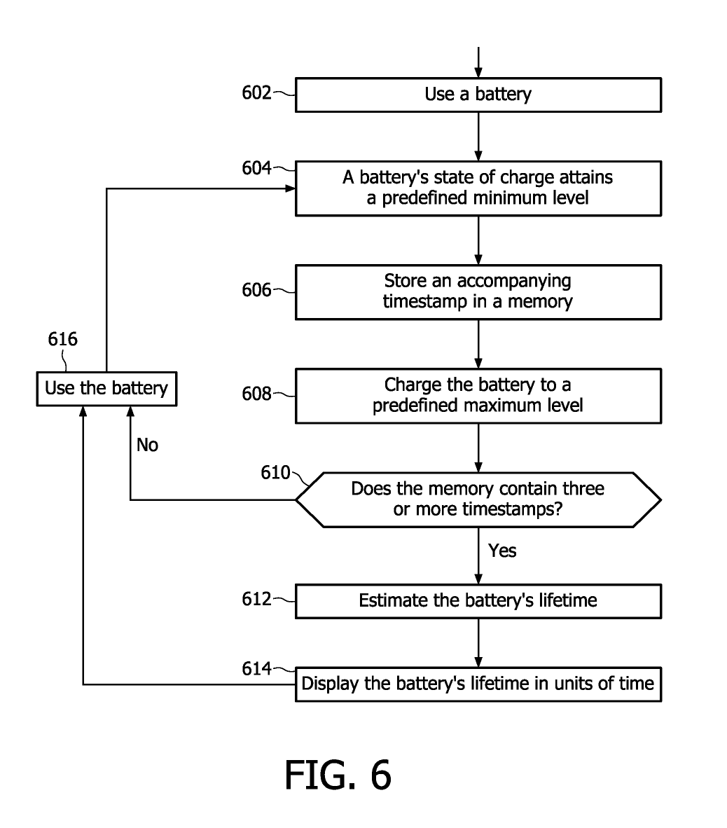

In a third embodiment according to the invention, time spans between consecutive points of time at which a battery's state of charge decreases from a predetermined maximum level to a predetermined minimum are monitored in order to estimate a battery's remaining lifetime. FIG. 6 depicts a flowchart which schematically explains this embodiment. Step 602 contains using a battery prior to a first instance of charging the battery. At step 604 the battery's state of charge attains the predefined minimum level at which charging is required. Step 606 comprises storing a numerical representation for an accompanying timestamp in a memory. Step 608 comprises charging the battery to the predefined maximum level using a charger known per se. At step 610 the contents of the memory are retrieved employing methods known per se. In case the memory contains three or more data time stamps, a battery's remaining lifetime is estimated at step 612 through a method explained below.

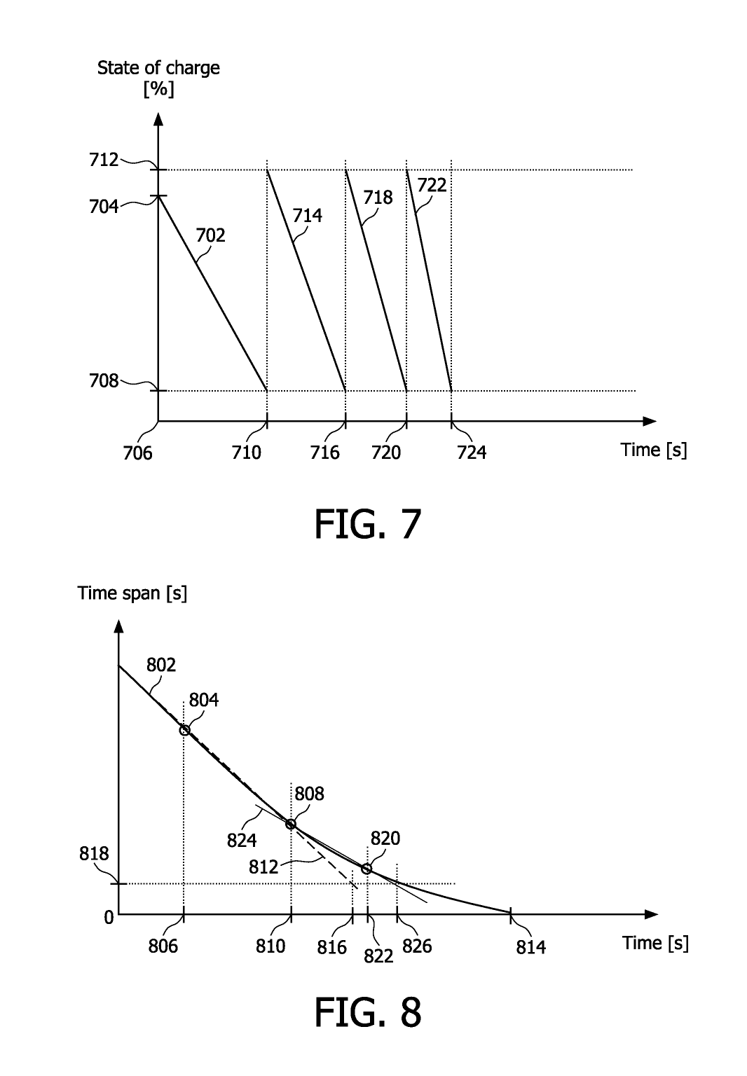

FIG. 7 schematically depicts a battery's state of charge 702 as a function of time prior to a first instance of charging the battery. By using the battery, the battery's state of charge 702 will decrease from an initial level 704 at a point of time 706 down to a predefined minimum level 708 at a point of time 710 at which the battery typically requires recharging. At the point of time 710 the battery is charged to a predefined maximum level 712. Due to using, a battery's state of charge 714 declines from the level 712 to the level 708 at a point of time 716 at which charging is required again. Likewise, a battery's state of charge 718 reduces from a level 712 to the level 708 at a point of time 720 at which charging becomes necessary. In like manner, after charging and due to using, a battery's state of charge 722 declines from a level 712 down to the level 708 at a point of time 724 at which charging is required once more.

FIG. 8 schematically displays a time span 802 between consecutive points of time at which the battery's state of charge decreases for the predefined maximum level 712 to the predefined minimum level 708. A sample 804 at a point of time 806 is determined by taking the absolute value of the numerical difference between the points of time 710 and 716. Herein the point of time 806 coincides with the point of time 716. Likewise, a sample 808 at a point of time 810 is established by computing the absolute value of the numerical difference between the points of time 716 and 720. In like manner, the point of time 810 corresponds to the point of time 720. On the basis of the samples 804 and 808, a linear extrapolation 812 is derived for the time span 802 between consecutive points of time at which the battery's state of charge decreases from the predetermined maximum level 712 to the predetermined minimum level 708.

A battery's end of life is defined as the moment at which the characteristic indicative for battery aging vanishes. Hence, the battery's end of life is attained at a point of time 814 since the aforementioned time span 802 then vanishes. An estimate for the point of time 814 is a point of time 816 at which the linear interpolation 812 intersects with a predefined critical level 818. The predefined critical level 818 is substantially higher than zero for reasons of safety. In case of a subsequent charging event, a sample 820 is obtained at a point of time 822. The sample 820 is established by the absolute value of the numerical difference between the points of time 720 and 724. The point of time 822 corresponds to the point of time 724. On the basis of samples 808 and 820, an updated linear extrapolation 824 is established. An estimate for the point of time 814 is a point of time 826 at which the linear interpolation 824 intersects with a predefined critical level 818. The battery's remaining lifetime at the point of time 822 is estimated by computing the absolute value of the numerical difference between the points of time 822 and 826.

Step 614, see FIG. 6, comprises graphically displaying the estimated battery's remaining lifetime to a user or a medical professional. Hereafter the battery is used in a continuous mode during step 616 until the battery's state of charge attains the predefined minimum level once more at step 604. Here a continuous mode implies a constant level of current drain.

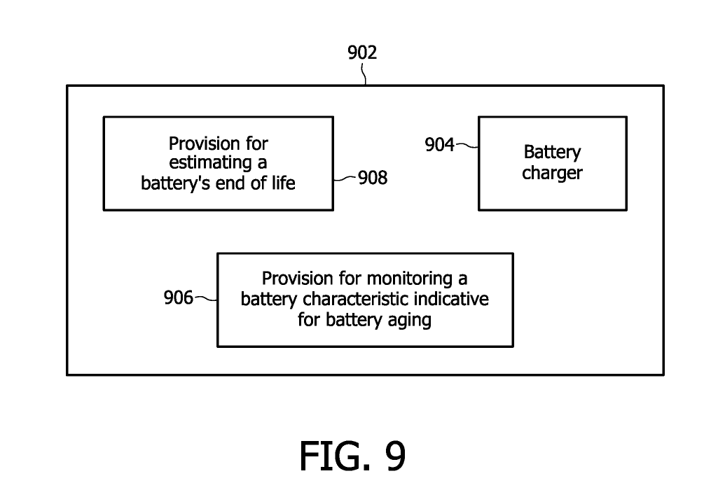

A fourth embodiment according to the invention is a device 902, see FIG. 9 for determining an end of life for a rechargeable battery. The device 902 comprises a battery charger 904 known per se. The device 902 further comprises a provision 906 for monitoring a battery characteristic indicative for battery aging and a provision 908 for estimating a battery's end of life.

While the invention has been illustrated and described in detail in the drawings and in the foregoing description, the illustrations and the description are to be considered illustrative or exemplary and not restrictive. The invention is not limited to the disclosed embodiments, for example, a battery's internal resistance can be used as a battery characteristic indicative for battery aging. Furthermore, it is possible to monitor a combination of battery characteristics indicative for battery aging.

It is noted that the method according to the invention and all its steps are made up of processes and materials known per se. It is further noted that the apparatus according to the invention and all its components can be made by applying processes and materials known per se. In the set of claims and the description the word “comprising” does not exclude other elements and the indefinite article “a” or “an” does not exclude a plurality. Any reference signs in the claims should not be construed as limiting the scope.

1. A method for determining an end of life for a rechargeable battery comprising charging the battery, monitoring a battery characteristic indicative for battery aging and making an estimation of a battery's lifetime.

2. The method according to claim 1, wherein a characteristic which is monotonically changing with time is used as the battery characteristic indicative for battery aging.

3. The method according to claim 1 wherein the estimation of the battery's lifetime is based on an extrapolation of data points of the battery characteristic indicative for battery aging.

4. The method according to claim 1 wherein the battery characteristic indicative for battery aging is monitored on a point of time at which the battery is being charged.

5. The method according to claim 1 wherein a battery's maximum capacity is used as the battery characteristic indicative for battery aging.

6. The method according to claim 1 wherein a rate of decay for a battery's state of charge is used as the battery characteristic indicative for battery aging.

7. The method according to claim 1 wherein a time span between consecutive points of time at which the battery's state of charge decreases from a predetermined maximum level to a predetermined minimum level is used as the battery characteristic indicative for battery aging.

8. The method according to claim 5 wherein the battery's maximum capacity is measured by determining a difference in a battery's state of charge before charging the battery and after charging the battery along with determining a charge added to the battery during charging the battery.

9. The method according to claim 6, wherein the battery's state of charge is determined by measuring a battery's potential and by employing a look-up table.

10. The method according to claim 5 wherein a charge added during charging the battery is determined by integrating a current flowing to the battery.

11. The method according to claim 1 wherein the battery's lifetime is expressed in units of time.

12. The method according to claim 1 wherein the battery's lifetime is displayed.

13. A device for determining an end of life for a rechargeable battery comprising a battery charger and a provision for estimating a battery's end of life characterized by a provision for monitoring a battery characteristic indicative for battery aging.
